(19) United States
(12) Patent Application Publication
(10) Pub. No.: US 2026/0103347 A1
(43) Pub. Date: Apr. 16, 2026

(54) SYSTEM AND METHOD FOR SCANNING THE CONDITION OF A STEEL CORD CONVEYOR BELT

(71) Applicant: Aleksey Gennadevich Pridorozhnyi, Moscow (RU)

(72) Inventor: Aleksey Gennadevich Pridorozhnyi, Moscow (RU)

(21) Appl. No.: 19/114,805

(22) PCT Filed: Apr. 24, 2023
(86) PCT No.: PCT/RU2023/000122

§ 371 Date: Mar. 25, 2025

(30) Foreign Application Priority Data
Jan. 26, 2023 (RU) 2023101713

(51) Int. Cl. B65G 43/02; G01R 33/038

(52) U.S. Cl. CPC B65G 43/02; G01R 33/038; B65G 2203/0275; B65G 2203/043

(57) ABSTRACT

The present technical solution relates to the field of monitoring the technical condition of technological objects, specifically to a system and method for scanning the condition of a wire-reinforced conveyor belt. The technical result is an improvement in the efficiency of monitoring the condition of the conveyor belt. This technical result is achieved by a system for scanning the condition of the wire-reinforced conveyor belt, the system including:
At least one magnet positioned across the conveyor belt, which provides magnetization of the steel wires of the conveyor belt;
At least one multi-channel scanner containing a group of magnetic field sensors (MFS), which scans the conveyor belt to obtain magnetic images that display signals from the scattering magnetic field (SMF) in the areas of splice connections and wire damages;
A computational unit that receives signals from the scanner and performs:
a) processing the obtained magnetic images to determine the size of wire damage and/or the condition of the splice connections in the conveyor belt, where the condition of the splice connections is characterized by at least their length;
b) determining the longitudinal and/or transverse coordinates of wire damages and/or the longitudinal coordinates of splice connection locations;
c) transmitting the data of the processed magnetic images, obtained in steps a) and b), to an external device.

### TECHNICAL FIELD

The present technical solution relates to the field of monitoring the technical condition of industrial equipment, specifically to a system and method for scanning the condition of a wire-reinforced conveyor belt of a belt conveyor.

### BACKGROUND ART

In various industries, such as mining, processing, energy, chemical, cargo handling, and others, conveyor transport is widely used for transporting bulk materials.

Transportation over long-distance conveyor systems can extend for several tens of kilometers. For such long-distance conveyors, wire-reinforced rubber conveyor belts are used due to their higher strength and lower elongation.

The structure of a wire-reinforced rubber belt consists of a wire-reinforced carcass (a layer of steel wires embedded in an adhesive rubber layer) and rubber covers (upper and lower). The steel wires are arranged in a single plane with a specific spacing. Typically, the spacing between the wires ranges from 10 to 20 mm (as specified in GOST R 56904-2016/Wire-reinforced rubber conveyor belts for the mining industry).

Ensuring the reliable and uninterrupted operation of the conveyor belt depends on maintaining the integrity of the wire-reinforced carcass and splice joints. Therefore, monitoring the condition of the wires and splice joints within the belt is essential.

During conveyor operation, damage to the wire-reinforced carcass and splice joints may occur due to impact forces or the jamming of heavy, large-sized ore pieces or foreign materials at loading points, material entrapment between the drum shell and the belt, or accidental contact of the conveyor belt with defective or stationary conveyor components. Additionally, steel wires are susceptible to fatigue failure due to cyclic bending and tensile stresses during conveyor operation or may degrade due to mechanical and/or chemical corrosion caused by friction between individual strands in the steel cord or moisture ingress. Splice joints may degrade and fail due to the loss of adhesion between the cord and the adhesive rubber layer in the splice joint, as well as due to the physical failure of the wires themselves.

All the aforementioned damages to the steel wires and splice joints lead to a loss of the belt's strength properties, increasing the risk of belt rupture. This, in turn, can result in unplanned stoppages and downtimes of the conveyor system, as well as potential injuries or even fatalities among maintenance personnel.

Given this risk, it is necessary to monitor the integrity of the steel wires and splice joints to detect damage at an early stage and conduct preventive maintenance during scheduled conveyor downtimes. In this regard, the Federal Service for Environmental, Technological, and Nuclear Supervision approved and enacted regulatory guidelines by Order No. 206 dated Apr. 4, 2008, titled “Methodological Recommendations on the Procedure for Conducting Industrial Safety Examinations of Wire-Reinforced Conveyor Belts Used at Hazardous Production Facilities” (RD-15-16-2008). According to RD-15-16-2008, periodic defectoscopy of the metal wires and splice joints is recommended.

Due to the significant length of conveyors and the fact that the wires and splice joints are embedded within the belt beneath rubber covers, detecting early-stage damage through visual inspection by maintenance personnel is extremely difficult.

This creates a demand for instrumental methods of non-destructive testing (NDT) that enable online inspection of the wires and splice joints during the conveyor belt's operation.

Currently, the inspection of wires and splice joints in conveyor belts is performed visually or using NDT methods. The most common NDT method is eddy current defectoscopy. An example of a defectoscope based on this principle is the INTROCON device (https://www.intron.ru/ru/pribory/introkon/).

The primary drawback of visual inspection is its inability to detect hidden defects, damages, or failures of steel wires and splice joints at an early stage, making this method highly ineffective.

The disadvantage of eddy current defectoscopy using the INTROCON system is that the magnetic defectogram, presented as a graph of electromagnetic response curves, is difficult to read and interpret. The detected defects are poorly visualized on the defectogram, and the defects lack precise transverse coordinates (analysis is performed in discrete channels, each 220 mm wide), which reduces the effectiveness of data interpretation, the accuracy of defect localization, and the level of detail. A specially trained specialist is required to read and interpret the magnetic defectograms presented as curve graphs. Splice joints are difficult to read and are not visualized on the defectogram, and there is no possibility of analyzing the internal structure of the splice joint.

### SUMMARY OF THE INVENTION

The disclosed invention aims to solve the technical problem of developing a more effective method for monitoring the integrity of the wires in the belt carcass and assessing the condition of splice joints in a wire-reinforced conveyor belt.

The technical result achieved is an increase in the efficiency of conveyor belt condition monitoring.

The claimed technical result is achieved through a system for scanning the condition of a wire-reinforced conveyor belt, wherein the system comprises:
At least one magnet positioned across the conveyor belt to magnetize the steel wires within the belt;
At least one multi-channel scanner comprising a group of magnetic field sensors (MFS) to scan the conveyor belt and obtain magnetograms displaying signals from the stray magnetic field (SMF) in the areas of splice joints and cord damage;
A computational unit that receives signals from the scanner and performs the following:
   a) Processes the acquired magnetograms to determine the size of cord damage and/or the condition of splice joints within the conveyor belt, wherein the condition of splice joints is characterized by at least their length;
   b) Identifies the longitudinal and/or transverse coordinates of cord damage and/or the longitudinal coordinates of splice joint locations;
   c) Transmits the processed magnetogram data obtained in steps (a) and (b) to an external device.

In one particular implementation of the system, the scanner is positioned at a distance of no more than 1000 mm from the surface of the belt.

In another particular implementation of the system, the group of MFS is arranged in a single row or in at least two rows.

In another particular implementation of the system, the MFS rows are arranged in a staggered pattern.

In another particular implementation of the system, the MFS registers at least one component of the SMF, selected from the group: longitudinal Bₓ, transverse B_{y}, or perpendicular B_{z}.

In another particular implementation of the system, the MFS are Hall effect sensors.

In another particular implementation of the system, the scanner includes magnetic flux concentrators that provide passive magnetic amplification and increase the output sensitivity of the MFS without increasing its intrinsic electrical noise.

In another particular implementation of the system, the concentrators are integrated into the MFS.

In another particular implementation of the system, the magnetic flux concentrators are rod-shaped or flat.

In another particular implementation, the transverse coordinate across the width of the belt is measured from the belt's edge or center.

In another particular implementation of the system, a shielding screen is installed above the scanner to protect it from external magnetic fields.

In another particular implementation of the system, the magnet is a permanent magnet or an electromagnet.

In another particular implementation of the system, the magnet is positioned at a distance of no more than 1000 mm from the surface of the belt.

In another particular implementation of the system, the magnetic axis of the magnet is perpendicular to the belt surface.

In another particular implementation of the system, the scanner is positioned downstream of the magnet along the conveyor belt's movement.

In another particular implementation, the system additionally includes a belt length counter that generates signals transmitted to the computational unit, characterizing the longitudinal length of the conveyor belt.

In another particular implementation of the system, the belt length counter is a non-contact tachometer or a proximity sensor mounted on a conveyor drum or roller, or an encoder with a wheel that contacts the moving belt.

In another particular implementation of the system, the belt length counter is integrated into the scanner or magnet.

In another particular implementation of the system, the external device is connected to the computational unit via a wired or wireless data transmission channel.

In another particular implementation of the system, the external device is a monitor, an interactive screen, a computer, a laptop, a tablet, a smartphone, a removable data storage device, a conveyor PLC, or a remote control system.

In another particular implementation of the system, the computational unit generates a digital report containing data on wire rope damage and the condition of spliced joints in the conveyor belt.

In another particular implementation, the system includes at least one video camera capturing video footage of the conveyor belt surface, synchronized with the magnetogram.

In another particular implementation of the system, the size of wire rope damage is characterized by the number of broken ropes within the detected damage area.

In another particular implementation of the system, the computational unit additionally determines at least one of the following parameters:
Sequential number of the spliced joint
Angle of inclination of the pole lines in the step of the spliced joint.
Degree of linearity of the pole lines in the step of the spliced joint
Area of the pole lines in the step of the spliced joint
Distance between different pole lines in the step of the spliced joint

In another particular implementation of the system, the computational unit is configured to filter out signals registered by the MFS whose levels are below a threshold value to eliminate background noise P_{background}.

In another particular implementation of the system, when determining the size of wire rope damage and the condition of spliced joints using the computational unit, the obtained magnetograms are compared with at least one threshold signal value P_{wire} set for wire rope analysis and at least one threshold signal value P_{splice} set for spliced joint analysis, where P_{splice}≥P_{wire}≥P_{background}.

In another particular implementation of the system, the computational unit determines the area of wire rope damage and the area of pole lines in the step of spliced joints based on the threshold values P_{wire} and P_{splice} for the MFS.

In another particular implementation of the system, the computational unit uses a threshold area level Swire to determine wire rope damage and a threshold area level S_{splice} to determine the pole lines in the step of a spliced joint and the spliced joints themselves, where S_{splice} is greater than S_{wire}.

In another particular implementation of the system, the computational unit establishes the fact of registering the pole lines in the step of a spliced joint and the spliced joint itself on the magnetogram when processing signals received from the scanner, provided that the signal equals or exceeds the threshold value P_{splice} and the area of the magnetic anomaly determined based on P_{splice} equals or exceeds the value S_{splice}.

In another particular implementation of the system, the computational unit establishes the fact of registering wire rope damage on the magnetogram when processing signals received from the scanner if the following conditions are met: the signal equals or exceeds the threshold value P_{wire} and the area of the magnetic anomaly determined based on P_{wire} equals or exceeds the value S_{wire}, provided that this magnetic anomaly is not registered as a pole line in the step of a spliced joint.

In another particular implementation of the system, the threshold signal level P_{wire} for the MFS is determined through calibration using calibration samples of the belt with predefined damage or is taken as equal to P_{background}, or is set automatically by the computational unit using an analytical calibration method.

In another particular implementation of the system, the threshold value P_{wire} is set automatically for each wire rope damage at a level corresponding to a certain percentage of the maximum signal value from that particular wire rope damage.

In another particular implementation of the system, the percentage of the maximum signal value from the wire rope damage for setting the threshold value P_{wire} is determined automatically based on the scanner's position parameters on the conveyor and the design parameters of the conveyor belt.

In another particular implementation of the system, the threshold value P_{wire} is set automatically in a differentiated manner for multiple damage classes.

In another particular implementation of the system, the computational unit performs magnetic mapping of the entire conveyor belt installation on the belt conveyor, determining the total belt length and displaying all spliced joints and wire rope damages on the belt, with an indication of the longitudinal coordinate along the belt.

In another particular implementation of the system, the first spliced joint on the magnetic map of the belt is designated as the leading or closing spliced joint of a belt section, with a predefined ranking number assigned based on section length, where the first section has the shortest length, and subsequent sections have greater lengths relative to the previous ones. The spliced joint of the section with the assigned ranking number, located first along the belt's movement, is designated as the leading joint, while the second is the closing joint, or the first spliced joint is set manually.

In another particular implementation of the system, the longitudinal coordinate of spliced joints and wire rope damages is measured from the first spliced joint or from a point on the belt located at a specified distance from the first spliced joint.

In another particular implementation of the system, the longitudinal coordinate of wire rope damages is measured from the leading and/or closing spliced joint of the belt section where the damage is located, or from a point on the belt at a specified distance from the leading and/or closing spliced joint of that belt section.

In another particular implementation of the system, the longitudinal coordinate of spliced joints and wire rope damages is measured from a visual, magnetic, or radio-frequency marker additionally installed on the conveyor belt.

In another particular implementation of the system, the computational unit is connected to the belt conveyor control system.

In another particular implementation of the system, the computational unit is connected to the belt conveyor control system using one of the following methods: via relay outputs, using the Modbus protocol, or via Profibus or Profinet networks.

In another particular implementation of the system, the computational unit is configured to generate a signal for the belt conveyor control system to stop the conveyor when the predefined damage level of wire ropes is exceeded. The damage level is characterized by at least one parameter selected from the group: damage size, measured by the number of broken wire ropes or their percentage of the total number of wire ropes in the belt; the total number of broken wire ropes from all detected damages in a belt section of a given length or their percentage of the total number of wire ropes in the belt.

In another particular implementation of the system, the computational unit is configured to generate a signal for the belt conveyor control system to stop the conveyor when a specified change in the condition parameter of a spliced joint exceeds a predefined threshold. This is determined by at least one parameter selected from the group: spliced joint length, angle of inclination of the pole lines in the spliced joint, degree of linearity of the pole lines in the spliced joint, distance between different pole lines of the spliced joint, area of the pole lines in the spliced joint, or total area of the spliced joint.

In another particular implementation of the system, the area of the spliced joint is determined as the total area of all pole lines in the spliced joint. Alternatively, it is characterized by two values, each representing the total area of the pole lines of one polarity, or by their difference, another combination of these two values, or as the area enclosed between the extreme pole lines of the spliced joint.

In another particular implementation of the system, the computational unit, connected to the belt conveyor control system, is configured to generate a stop signal for the belt conveyor in such a way that the section of the belt with wire rope damage or the spliced joint is positioned at a predefined distance from the scanner.

In another particular implementation of the system, the computational unit is integrated into the scanner.

The claimed technical result is also achieved through a method for scanning the condition of a wire-rope conveyor belt in a belt conveyor. The method includes the following steps:
Magnetizing the wire ropes of the conveyor belt using at least one magnet placed across the conveyor belt.
Scanning the conveyor belt with at least one multi-channel scanner containing a group of magnetic field sensors (MFS). During scanning, magnetic images (magnetograms) are obtained, displaying signals from the stray magnetic field (SMF) in the areas of spliced joints and wire rope damages.
Receiving signals generated by the scanner in a computational unit, which performs the following tasks:
a) Processing the obtained magnetograms to determine the size of wire rope damages and/or the condition of spliced joints in the conveyor belt. The condition of spliced joints is characterized at least by their length.
b) Determining the longitudinal and/or transverse coordinates of wire rope damages and/or the longitudinal coordinates of spliced joint locations.
c) Transmitting the processed magnetogram data obtained in steps (a) and (b) to an external device.

### BRIEF DESCRIPTION OF THE DRAWINGS

FIG. 1 shows the general view of the claimed system.

FIG. 2 shows a schematic view of the scanner.

FIG. 3 shows an example of registering the scattering magnetic field (MPF) in the area of the integrity violation (break) of a steel wire.

FIG. 4A shows an example of measuring magnetic field components in the area of a wire break.

FIG. 4B shows an example of a bipolar signal from a magnetic field sensor in the area of a wire break when registering the perpendicular component B_{z} of the MPF.

FIG. 4C shows an example of a signal from a magnetic field sensor in the area of a wire break when registering the longitudinal component Bₓ of the MPF.

FIG. 5A shows an example of the formation of pole lines in a 1-stage splice connection.

FIG. 5B shows a schematic view of splice connections of different step levels.

FIG. 6 shows an example of damage to wires.

FIG. 7 shows an example of a splice connection display.

FIG. 8 shows the determination of the magnetic anomaly area based on the signal threshold value.

FIG. 9 shows an example of determining the distance from the magnetic field sensors to the surface of the belt and the plane of the wires.

FIG. 10 shows an example of broken wires in the damage area and the line in the cross-section A-A, along which the signal distribution is calculated using mathematical modeling.

FIG. 11A shows an example of model calculation of signals from magnetic field sensors in the area of seven broken wires and different threshold levels for the signals from the magnetic field sensors.

FIG. 11B-FIG. 11G show an example of model calculation of signals from magnetic field sensors in the damage area with varying numbers of broken wires and the selection of an optimal threshold value for determining the number of broken wires.

FIG. 12 shows the calculation of the optimal percentage level for the threshold signal value P_{wire} depending on the number of broken wires in the damage.

FIG. 13 shows an example of damage distribution by groups depending on the number of broken wires in the damage.

FIG. 14 shows an example of splice placement on the belt's magnetic map.

FIG. 15 shows the general view of the computing device.

### DETAILED DESCRIPTION OF THE INVENTION

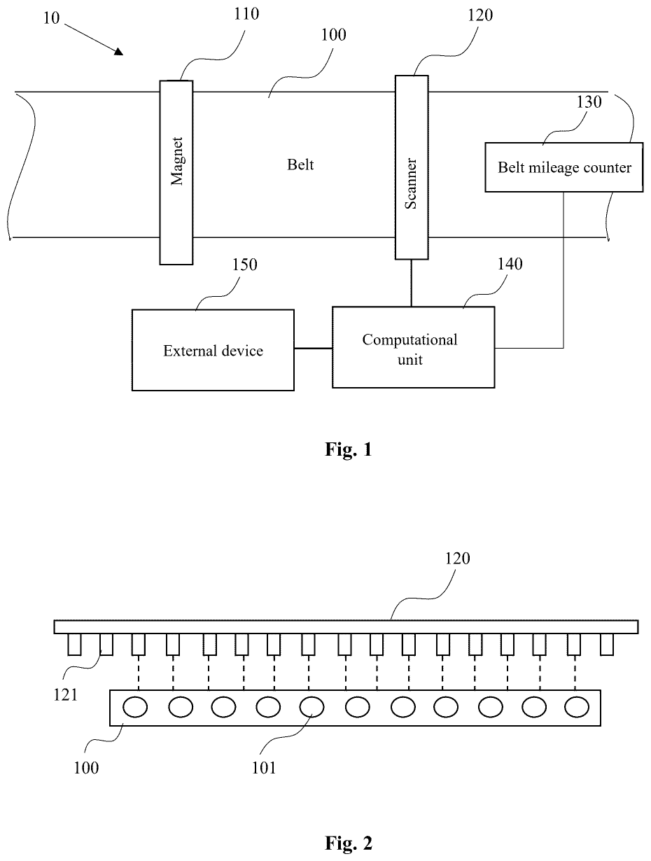

FIG. 1 shows the claimed system (10) for scanning the state of the wire belt (100), which generally includes a magnet (110), a scanner (120), a computing block (140), and an external device (150) connected to it. Additionally, a belt meter counter (130) may be used, the operation of which will be described later in this description. Data from the scanner (120) and the belt meter counter (130), if used, are sent for further processing to the computing block (140).

FIG. 2 shows a schematic view of the scanner (120). The scanner (120) contains a group of magnetic field sensors (121) (MFS) and is installed above or below the surface of the belt (100). As sensors (121), Hall effect sensors, for example, may be used. MFS (121) register scattering magnetic fields (SMF) generated by the damaged steel wires (101) of the belt (100), which are magnetized using the magnet (110), which is a permanent magnet or an electromagnet. The magnet (110) is positioned at a distance h₃ from the surface of the conveyor belt, with h₃ preferably not exceeding 1000 mm. The belt (100) can be in a flat, tray-shaped, or tubular state. It is preferable to place the magnet (110) in such a way as to achieve uniform magnetization of all wires across the width of the belt (100), particularly at the same distance from the surface of the belt (100). To strengthen the magnetic field in the belt (100), a second magnet may be used on the same or the opposite side of the belt (100).

The scanner (120) outputs signals from the MFS (121), which are transmitted to the computing block (140) to form a magnetic map and its subsequent analysis. The scanner (120) is a panel made in the form of a printed circuit board in a housing containing an integrated circuit to which the MFS (121) are connected. The connection of the scanner (120), as well as the belt meter counter (130), to the computing block (140) can be carried out using standard interfaces, such as USB, multi-wire ribbon, coaxial wire, DB25 pin connector, or any other suitable type of interface.

In the case of damage to the wire (101), magnetic field scattering occurs at this location, which is recorded by a series of MFS (121) arranged across the belt (100) with a specific step. The scanner (120) may contain one or several rows of MFS (121), which can be arranged in various ways, such as in a checkerboard pattern, one after another, with a set offset, etc. The increase in the scanner's transverse resolution and the accuracy of determining the location of the damage is achieved by reducing the step (discretization) of the MFS (121) relative to each other. The step of positioning the MFS (121) is limited by their physical size, which is typically around 3 mm.

The scanner (120) is positioned at a distance from the surface of the conveyor belt (100), usually no more than 1000 mm.

To avoid induction (shadows) from large damages and splice connections from the sections of the belt that are not directly in the scanning process but pass along another branch of the conveyor and remotely create interference to the working scanner (120), a protective shielding sheet, such as steel, may be installed to shield the scanner (120) from the possible source of magnetic interference.

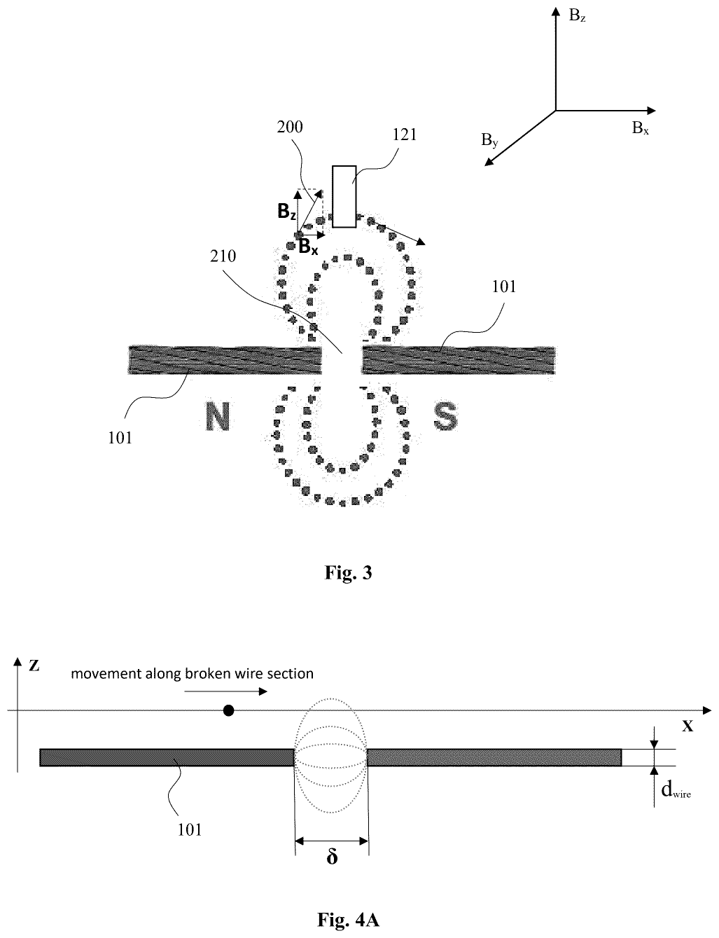

As shown in FIG. 3, at each damage detection point of the wires (101), at least one MFS (121) is used, which allows for the registration of at least one of the three projections of the magnetic field scattering vector intensity, namely: along the length of the belt (longitudinal projection) Bₓ, across the width of the belt (transverse projection) B_{y}, or perpendicular to the surface of the belt (perpendicular projection) B_{z}.

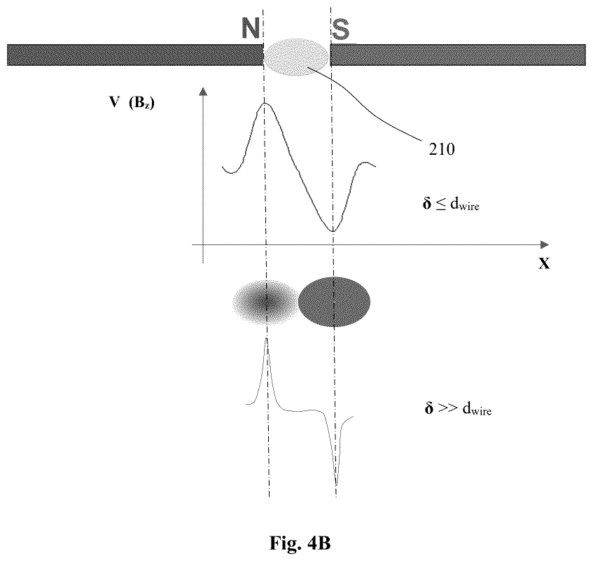

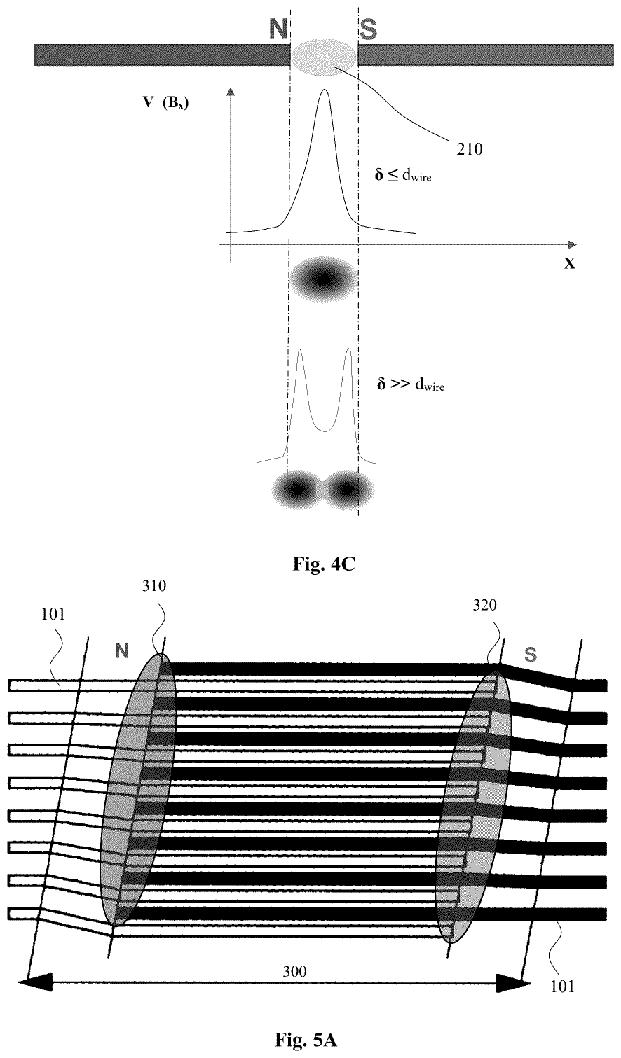

As shown in FIG. 4A, moving over the surface of the conveyor belt (100) along the damaged wire directly over the area of its break, the longitudinal and vertical components of the magnetic scattering field Bₓ and B_{z} reach their maximum/minimum values and have a distinct characteristic distribution pattern in the damage area. At the same time, the transverse component of the magnetic field scattering B_{y} does not have a characteristic distribution pattern and remains in the zero-value area when moving along the above line. Therefore, B_{y} is not very convenient for detecting and analyzing damage to the steel wires (101). It is most reasonable to register the longitudinal Bₓ or vertical (perpendicular) B_{z} components of the magnetic field.

To detect the damage area (210), it is sufficient to register at least the perpendicular (vertical) B_{z} or longitudinal Bₓ component (projection) of the magnetic field (200). For example, the analog response of the MFS (121) when registering the vertical projection of the magnetic field represents a bipolar electrical signal, as shown in FIG. 4B.

The maximum and minimum of the bipolar signal when registering the vertical projection of the SMF correspond to the poles of the magnetic field at the opposite ends of the wire (101) at the break (210). The point where the signal polarity changes corresponds to the center of the damage. Digital processing of the bipolar signal using the computational unit (140) allows for the identification of regions with increased magnetic field intensity and polarity change, corresponding to different poles at the opposite ends of the broken wire and the center of the break (101) to visualize the damage area (210).

As shown in FIG. 4B, if the gap δ between the ends of the broken wire is insignificant (the opposite ends of the wire may be in contact or be at a distance comparable to the diameter of the wire δ≤d_{wire}), then one characteristic maximum of the Bₓ component distribution is formed above the center of the damage. However, if the damage has a greater extent (the distance between the ends of the wires is much larger than the diameter of the wire δ>>d_{wire}), the single maximum above the center of the damage splits into two characteristic maxima of the Bₓ component distribution, shifted from the center of the break closer to the ends of the broken wire, with a weakening in the middle of the damage. As shown in FIG. 4B, when measuring the vertical component B_{z}, in both cases, δ≤d_{wire} and δ>>d_{wire}, the distribution pattern of the vertical component of the field has a similar bipolar symmetrical appearance relative to the center of the damage, with a maximum and minimum at the edges of the damage and a polarity change at the center of the damage, with the only difference being that when δ>>d_{wire}, the bipolar response from the MFS (121) essentially splits into two unipolar signals of opposite polarity (a situation typical for the polar lines of a stepped splice connection).

The vertical component of the magnetic field scattering B_{z} makes the most significant contribution to the effective operation of the proposed solution, since regardless of the size of the damage, its distribution always has a bipolar form with a polarity change at the center of the damage and extreme values at the edges of the damage, which allows for the clear identification of the location and boundaries of the damage.

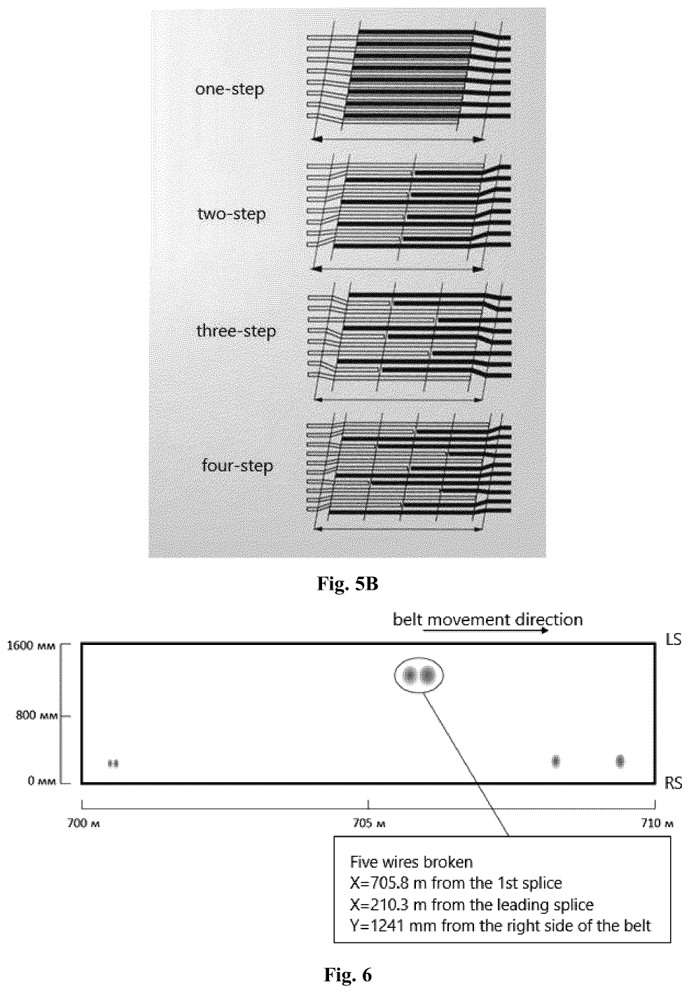

FIG. 5A shows an example of the formation of polar lines of a step (310, 320) in the region of a 1-step splice connection (300), corresponding to the northern (310) and southern (320) magnetic poles when measuring the vertical component B, of the SMF. Since in the splice connection area (300), the wires (101) have open ends, magnetic field scattering similar to that of wire breaks (101) occurs in splice connections (300), forming opposite poles (N, S) at the ends of the wires (101).

The splice connection can be multi-stepped, i.e., it can have two, three, or more steps, with schematic images of splice connections with different step structures shown in FIG. 5B. At each step of the splice connection, polar lines will form, similar to those shown in FIG. 5A. On the tape's magnetogram, the splice connection is represented as a series of polar lines of its components. The location and shape of the polar lines of the step, such as their linearity, tilt angle, area, and distance from each other, are important indicators of the condition of the splice connection in the tape (100), which must be promptly monitored during its operation. Thus, in the splice connection area (300), polar lines (310, 320) are formed, which can be registered as areas of increased magnetic field intensity and visualized after subsequent digital signal processing.

The SMF, resulting from wire (101) damage or in the splice connection area (300), generates an electrical analog signal at the output of the MFS (121), which is then amplified, multiplexed (if necessary), and converted into a digital form using an ADC in the scanner (120), and further processed in the processor of the computational unit (140). In a specific case of implementing the solution, each of the operations listed: amplification of signals from the MFS (121), switching (multiplexing) of signals from the MFS, and conversion of the analog signals from the MFS to a digital form using the ADC, can be performed either directly in the scanner (120) or in the computational unit (140), depending on the technical implementation method. The computational unit (140) may be an integral part of the scanner (120) or connect to it to form a single device. The presented example of hardware implementation does not limit possible variations of device combinations and their functionality within the scope of the proposed solution.

The longitudinal coordinate “x” along the magnetogram of the conveyor belt (100) can be calculated algorithmically (through software processing) using the computational unit (140), for example, based on the specified speed of the conveyor belt (100) or the speed obtained from the conveyor belt speed sensor (100) and the scanning time. The speed of the belt (100) is typically a set parameter, and by multiplying the specified belt speed by the scanning time, the length of the belt or a specific section can be calculated. Additionally, the speed data can be obtained, for example, from the belt speed sensor. By multiplying the speed data by time, the data for the belt length can be obtained.

When using the belt length counter (130), pulses from the belt length counter (130) are sent to the computational unit (140). This counter may be in the form of a contactless tachometer or proximeter mounted on the drum or roller of the conveyor, or an encoder with a wheel that rotates due to contact with the moving belt (100). The belt length counter (130) can be based on a belt speed sensor. Any other suitable type of belt length counter can also be used. The counter (130) may be integrated (built-in) into the magnet (110) or scanner (120). The belt length counter (130) allows for more accurate determination of the longitudinal length along the conveyor belt (measurement scale along the X-axis).

The obtained data stream from the MFS from the scanner (120) and data from the belt length counter (130), if used, is processed by the computational unit (140). By processing the data from the scanner (120), magnetograms of the scanned belt (100) are generated for subsequent report generation, which contains information about the damage to the wires (101) and the condition of the splice connections (300). The scanning report can be transmitted to an external device for viewing and visualization, such as a monitor, computer, laptop, etc., and/or in the form of a report in digital format (digital file), such as a PDF document (or another format), which can be saved on an external device (150) in the form of a removable data storage device (e.g., USB flash drive, removable HDD/SSD, etc.).

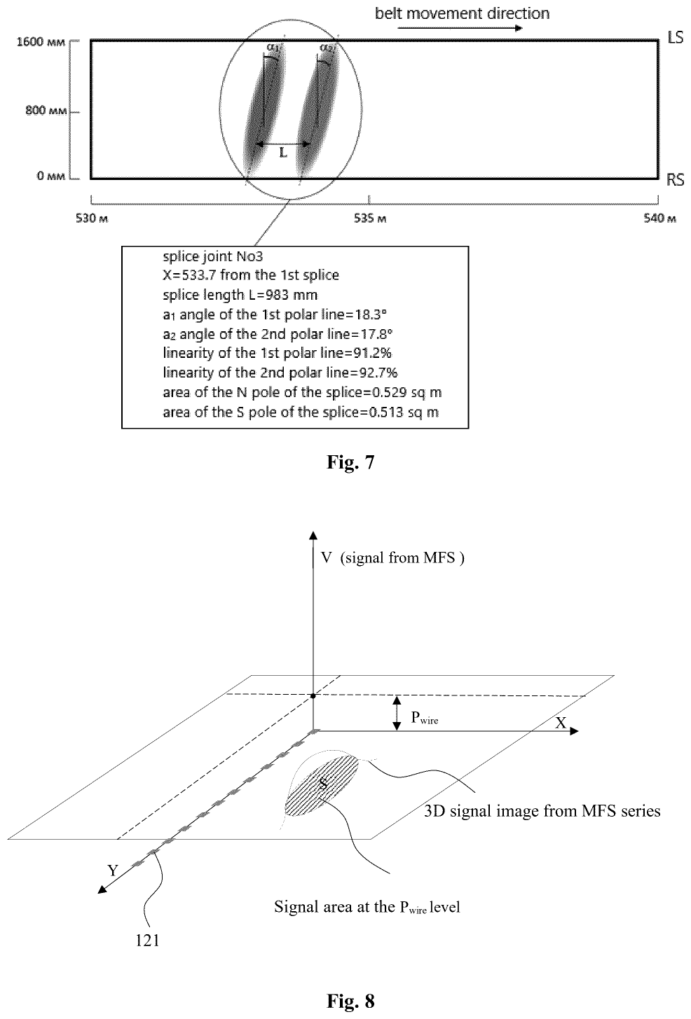

The scanning report may present visualized images of damage (FIG. 6) and splice connections (FIG. 7), showing areas of increased magnetic field intensity at the formed poles, indicating longitudinal coordinates along the belt (100) for splice connections and coordinates along the width and length of the belt (100) for the damaged areas of the wires, as well as the number of broken wires (101) in the damage.

Additionally, the system may use one or more video cameras, which allow video images of the surface condition of the conveyor belt to be obtained. These images can also be transmitted to the computational unit (140) for comparison (synchronization of the video image) with the magnetogram of the corresponding section of the belt to gather additional information about the damage to the wires and splice connections at that location on the belt. This later enables the gathering of information about the damage based on both the magnetograms and the corresponding video image of the belt, which displays the damaged area or splice connection. This can be displayed using a graphical user interface (GUI) and allows the operator to highlight areas of the belt (100) for further analysis.

The scanning report can be sent to an external device (150), such as a monitor, interactive screen, laptop, smartphone, tablet, or computer with a monitor or display for viewing and visualization. The device (150) allows the report on the belt's condition (100) to be displayed in the GUI, where operations can be performed on the visualized data for subsequent monitoring of the technical condition of the belt (100). Data transmission from the computational unit (140) to the device (150) can be carried out using known communication methods, both wired (LAN, USB, LPT, etc.) and wireless types (TCP/IP, WLAN, Wi-Fi, GSM, etc.).

The computational unit (140) can be any suitable solution capable of performing the software-logical processing of incoming signals from the scanner (120) and the belt length counter (130), if used. For example, the block (140) can be a system on a chip (SoC), a software-hardware computing module, a processor, controller, microprocessor, microcontroller, PLC, computer (including single-board computers), tablets, etc.

To increase the sensitivity of the SMF measurements in the area of the steel wire break (210) and splice connections (300) of the conveyor belt (100), it is proposed to use ferromagnetic flux concentrators along with the MFS (121), which provide passive magnetic amplification and increase the output sensitivity of the MFS without increasing its own electrical noise. The concentrators can be integrated into the MFS (121) or installed on the scanner board (120) at a specified distance from the MFS (121) or in contact with the MFS (121). The concentrators can be rod-shaped or flat.

Various examples of magnetic concentrators are known in the prior art (see, for example, SU 1757364 A1). The effect of magnetic field concentration is based on increasing the magnetic flux density inside a ferromagnetic material (the external magnetic field is “pulled” inside the ferromagnetic material), which has a higher magnetic permeability compared to the surrounding environment (μ>>1) (Hall Effect Devices, Second Edition, R. S. Popovic, Swiss Federal Institute of Technology Lausanne (EPFL), Institute of Physics Publishing, Bristol and Philadelphia, 2004). The MFS can be used with concentrators in the form of long rectangular, axisymmetric, or other types of rods with a conical tip, rounded or shaped in another form (Hall Effect Devices, Second Edition, R. S. Popovic, Swiss Federal Institute of Technology Lausanne (EPFL), Institute of Physics Publishing, Bristol and Philadelphia, 2004; Repository of the Belarusian National Technical University (BNTU), Instruments and Measurement Methods, 1 (6), 2013, SU 1757364 A1, Parameters of the Miniature Hall Element with Magnetic Flux Concentrators as a Four-Pole. Yarmolovich V. A., NAN Belarus in Materials Science, Minsk, Republic of Belarus).

The magnetic amplification of the concentrator G_{M} is determined by the ratio G_{M}=B*/B, where B* is the magnetic field induction at the location of the MFS, and B is the magnetic induction of the external magnetic field. The magnetic amplification G_{M} achieved by a flat concentrator is determined by the ratio G_{M}˜L/t, where the concentrator magnetic permeability is μ>>1, L (length of the concentrator)>>t (thickness of the concentrator), W (width of the concentrator)>>t, and g/t→0, where g is the gap between the ends of the concentrator where the MFS is placed. The result of 2D mathematical modeling for the case L=33t, g=t, and W>>t shows that using a flat magnetic field concentrator allows the magnetic field to be amplified up to 10 times (Hall Effect Devices, Second Edition, R. S. Popovic, Swiss Federal Institute of Technology Lausanne (EPFL), Institute of Physics Publishing, Bristol and Philadelphia, 2004).

Flat magnetic field concentrators can also be used, which convert the magnetic field parallel to the MFS surface into an enhanced perpendicular field, which is then registered by the MFS (121). Two MFS are placed under the flat concentrator at each of the opposite ends of the concentrator. Since in this scheme, the two MFS measure the perpendicular component of the magnetic field in opposite directions, subtracting their values results in their actual addition. If these two sensors work together, they effectively double the measurement sensitivity and, additionally, are insensitive to the external perpendicular magnetic field. The arrangement of MFS with such concentrators is described in the work “Hall Effect Devices, Second Edition, R. S. Popovic, Swiss Federal Institute of Technology Lausanne (EPFL), Institute of Physics Publishing, Bristol and Philadelphia, 2004.”

The maximum value of magnetic amplification GM is achieved when the MFS are placed directly on the concentrator and positioned at the very edge of the concentrator. In this case, with g˜t and L>>t, the magnetic amplification GM is given by GM˜L/t.

When working with flat magnetic field concentrators, where the MFS are located at the edge of the concentrator, the two MFS always work in tandem to ensure that the paired system is insensitive to the component of the external magnetic field perpendicular to the surface of the MFS, while also providing double amplification of the measured signal from the component of the external magnetic field parallel to the surface of the MFS.

Soft magnetic materials can be used as the material for the concentrators. The magnetic flux amplification value for a rod concentrator, the material type of the concentrator, and its geometric dimensions are provided in Table 1 below (Repository of the Belarusian National Technical University (BNTU), Instruments and Measurement Methods, 1 (6), 2013, Parameters of the Miniature Hall Element with Magnetic Flux Concentrators as a Four-Pole. Yarmolovich V. A., NAN Belarus in Materials Science, Minsk, Republic of Belarus).

TABLE 1
Magnetic Flux Amplification k Values

| | Value k | |
|---|---|---|
| | Concentrator material | Concentrator |
| Geometry, concentrator | (Steel 1117) high- | material |
| length L, mm | permeability ferrite | (supermendur) |
| 100 | 404 | 1006 |
| 80 | — | 820 |
| 60 | — | 635 |
| 30 | 177 | 355 |
| 10 | — | 132 |

The use of magnetic concentrators allows for the enhancement of magnetic flux and significantly increases the magnetic sensitivity of the MFS.

### Determining Wire Damage

Based on the data received from the MFS (121) from the scanner (120) and the belt mileage counter (130), if used, the computational unit (140) generates a magnetic image of the belt, and for wire damage (101), the following characteristics are determined: the longitudinal and transverse coordinates of the damage (x, y) and the number of broken wires in the damage. The “x” coordinate of the damage is determined along the belt (100) from the first joint (300), which can, for example, be defined as the joint preceding or following the shortest section of the joined belt, or from any other joint or from a point on the belt located at a specified distance from the selected joint or from a visual, magnetic, RFID, NFC, or other type of marker additionally placed on the conveyor belt. Also, the additional “x” coordinate of the damage may be counted from the leading and/or closing joint of the belt section where the damage is located or from a point on the belt at a specified distance from the selected joint. The belt (100) on the conveyor is joined into an endless loop from separate pieces (sections) of the belt, so each section of the belt has two joints at its ends; the joint first in the direction of the belt is called the leading joint, and the second joint in the direction of the belt is called the closing joint.

Damage is detected by the MFS system (121) in the area where the signal magnitude from the MFS (121) is equal to or above a certain set threshold level P_{wire}, and the area of the magnetic anomaly defined at the threshold level P_{wire} is equal to or exceeds S_{wire}, provided that this magnetic anomaly is not registered as a pole line of the splice joint. A schematic determination of the magnetic anomaly area based on the threshold value P_{wire} is shown in FIG. 8. The area of the magnetic anomaly from the broken wires S_{wire} can be determined, for example, by the number of pixels in the magnetic image. The longitudinal “x” coordinate of the damage can be determined, for example, by measuring the perpendicular component of the scattered magnetic field as the center of the bipolar signal (the point of polarity change), or as the point midway between the maximum and minimum of the bipolar signal from the MFS (121), provided that the maximum and minimum of the bipolar signal are spaced no more than a specified distance apart, or as the point of the maximum value for each of the unipolar signals from the MFS (121) obtained as a result of the splitting of the bipolar signal due to the large distance between the opposite ends of the broken wire, or by another analytical signal processing method from the MFS (121), for example, using wavelet transformations.

The transverse “y” coordinate of the damage is recorded, for example, by the channel of the MFS (121) where the signal magnitude is maximum, or it is determined as the coordinate corresponding to the maximum of the curve obtained by approximating or interpolating the signal levels from the MFS channels when registering the magnetic field disturbance (MFD) from the damage. This coordinate is counted from the right or left edge of the belt, or its center, considering the position of the scanner relative to the belt.

The number of broken wires in the damage can be determined based on the transverse width of the signal at the specified threshold level P_{wire} (the area where the signal level exceeds a specified threshold value P_{wire}) and the specified step size of the wires on the belt. For example, dividing the width of the signal by the step size of the wires gives the calculated number of broken wires in the damage. In other words, the signal width, measured in wire step units, equals the number of broken wires in the damage. The width of the signal and the calculated number of broken wires in the damage will depend on the threshold level P_{wire}. The calculated number of broken wires in the damage may differ from the actual number. To ensure the calculated number of broken wires matches the actual number as closely as possible, the threshold signal value needs to be calibrated on test samples of the belt with a specified number of broken wires or through analytical (calculation-based) calibration, which will be described later in the application materials.

### Joint Connections

For joints (300), based on the data from the scanner (120) and the belt mileage counter (130), if used, the computational unit (140) measures the longitudinal “x” coordinate and at least one of the following joint connection parameters: the ordinal number of the joint, the length of the joint, the angle of inclination of the pole lines of the step in the joint connection, the degree of linearity of the pole lines in the joint connection, the distance between different pole lines of the joint, the area of the joint, or other characteristics. The length of the joint is a very important parameter because, for example, excessive elongation of the joint during operation indicates its degradation and destruction, which can lead to a loss of its strength characteristics and, consequently, a rupture of the belt in the joint area. Similarly, violations of linearity, changes in the angle of inclination, the distance between individual pole lines of the joint, and the area of the pole lines in the joint indicate damage and/or destruction of the primary structure of the joint created during the conveyor belt splicing work, which may also indicate joint failure and the emergence of an emergency situation.

The longitudinal “x” coordinate of the joint connection (300) is counted from the first joint connection (300), which, for example, can be defined as the joint that precedes or follows the shortest segment of the spliced belt or from any other joint connection or from a location on the belt located at a specified distance from the chosen joint connection or from a visual, magnetic, radio frequency (RFID, NFC, etc.), or other type of marker additionally installed on the conveyor belt. The longitudinal “x” coordinate of the joint connection along the belt can, for example, be defined as the “x” coordinate of the geometric center of all the pole lines of the step (the areas of the north (310) and south (320) poles) of this joint, or by another analytical method.

The length of the joint connection can be determined, for example, as the distance between the outermost pole lines of the step. The linearity and the angle of inclination of the pole lines of the step are determined through computer processing of the pixel array of the pole lines of the step. The area of the joint connection can be defined as the total area of all the pole lines of the step in the joint connection, or characterized by two values, each representing the total area of pole lines of one polarity, or the difference or another combination of these two values, or as the area enclosed between the outermost pole lines of the joint connection. The area of the pole lines of the step can be determined as the pixel area on the magnetic diagram or as a metric area, based on the longitudinal and transverse coordinate scales on the magnetic diagram. All calculations are automatically performed using the computational unit's (140) algorithm.

### Analytical (Calculation) Calibration

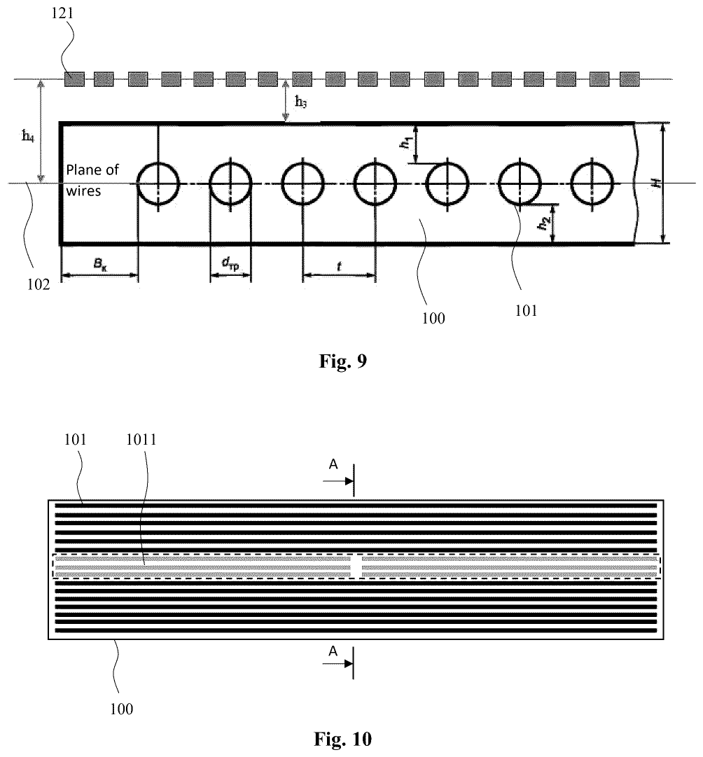

To determine the size of the wire damage (the number of broken wires), it is necessary to select an appropriate threshold signal level P_{wire}. The magnitude of the signal from the MFS (121) depends on the distance h₄ from their position to the plane of the wires (102), as shown in FIG. 9.

Using the method of mathematical modeling, it is possible to obtain, for example, the

$$B = \frac{{µ}_{θ}}{4 π} \frac{{p}_{m}}{{r}^{2}} \sqrt{1 + 3 {cos}^{2} θ} ,$$

distribution of the signal level from the longitudinal component Bₓ of the magnetic field scattering from the broken wires (1011) across the belt (100) along the section line A-A (Y-axis) above the broken wires (1011) at the center of the break, as shown in FIG. 10, at a distance h₄ from the plane of the wires. The magnetic field magnitude at each point is the sum of the magnetic fields from each broken wire. The rupture of each wire (101) can be treated as a separate magnetic dipole, the field of which decreases proportionally to the cube of the distance (Course of General Physics, Volume 2, Electricity and Magnetism, Waves, Optics, Second Edition, Moscow “Nauka”, Main Editorial Board of Physical and Mathematical Literature, 1982).

As a result, the total scattering field and, accordingly, the signal from the MFS (121) is proportional to the sum Σ1/rᵢ³, where rᵢ is the distance from the i-th broken wire (magnetic dipole) to the MFS (121), determined using the Pythagorean theorem, based on the difference in the coordinates of the MFS and the broken wire on the Y-axis and the distance h₄. The distribution of the signal level V(y) along the Y-axis across the belt above the center of the wire break (section A-A, at θ=90, the formula for the dipole field takes the form B=μ₀/4π*pₘ/r³, where pₘ is the magnetic dipole moment) is determined as the sum of the responses from each individual dipole (broken wire):

$$V ( y ) = C * {\sum }_{i = - ( n - 1 ) / 2}^{( n - 1 ) / 2} {[ {( y - 1 )}^{2} + {h}_{4}^{2} ]}^{- 3 / 2}$$

where C is a proportionality constant, taking into account the sensitivity of the MFS (121), the magnetic dipole moment of the broken wire pₘ, and the magnetic constant μ₀; y is the location of the MFS (121) on the Y-axis across the belt in units of wire step t (the coordinate center is located at the center of the damage); n is the number of broken wires in the damage; i is the index running through the location of all damaged wires on the Y-axis from −(n−1)/2−(n−1)/2−(n−1)/2 to (n−1)/2 with a step of one. Essentially, these are the coordinates of the broken wires on the Y-axis in units of wire step t; h₄ is the distance from the MFS to the plane of the wires in units of wire step t.

As an example, consider the case where the MFS (121) is located above the wire plane (102) at a distance of four wire steps h₄=4t. With this arrangement, the distance from the MFS (121) to the surface of the belt h₃ will range from 27 mm to 55 mm (GOST R 56904-2016/Wire-reinforced conveyor belts conveyor belts for the mining industry). This distance is sufficient to avoid possible contact with the moving belt in the event of its vibration. An example calculation for h₃ is given in Table 2.

TABLE 2

Values for belts of strength of belt bearing width, N/mm

| | | | | | | | |
|---|---|---|---|---|---|---|---|
| Parameter | 1000 | 1500 | 2000 | 2500 | 3150 | 4000 | 5000 |

| | | | | | | | | |
|---|---|---|---|---|---|---|---|---|
| Wire | Nominal | 4.20 | 4.20 | 6.00 | 5.40 | 7.50 | 8.25 | 10.60 |

| | | | | | |
|---|---|---|---|---|---|
| diameter, mm | Max deviation | +0.10 | +0.20 | +0.30 | +0.50 |
| | | −0.30 | −0.40 | −0.40 | −0.50 |

| | | | | | | | |
|---|---|---|---|---|---|---|---|
| Breaking tension of wire, N | 15680 | 25580 | 28400 | 41160 | 50960 | 76000 | 96040 |
| (kg/s), not less than | (1600) | (2610) | (2898) | (4200) | (5200) | (7755) | (9800) |

| | | | | | | | |
|---|---|---|---|---|---|---|---|
| Wire step, t, mm | Nominal | 14.0 | 9.0 | 15.0 | 12.0 | 14.0 | 17.5 |

| | | | |
|---|---|---|---|
| | Max deviation | ±2.0 | ±1.5 |
| Nominal | working (upper) | 7 | 10 |

| | |
|---|---|
| thickness | surface of belt, h1 |

| | | | |
|---|---|---|---|
| of rubber | non-working | 7 | 10 |

| | |
|---|---|
| covers | (lower) surface of |
| mm | belt, h2 |

| | | | | | | |
|---|---|---|---|---|---|---|
| Belt thickness, mm | 18.2^{+1.0}_{-2.0} | 20.0 ± | 19.4^{+1.0}_{-2.0} | 20.5^{+1.5}_{-2.0} | 22.5 ± | 30.5 ± 2.0 |

| | |
|---|---|
| 2.0 | 2.0 |

| | | | | | | | |
|---|---|---|---|---|---|---|---|
| h₄ = 4t, mm | 56 | 36 | 60 | 48 | 56 | 56 | 70 |
| h₃ = h₄ − h₁ − d_{wire}/ 2, mm | 47 | 27 | 50 | 38 | 45 | 45 | 55 |

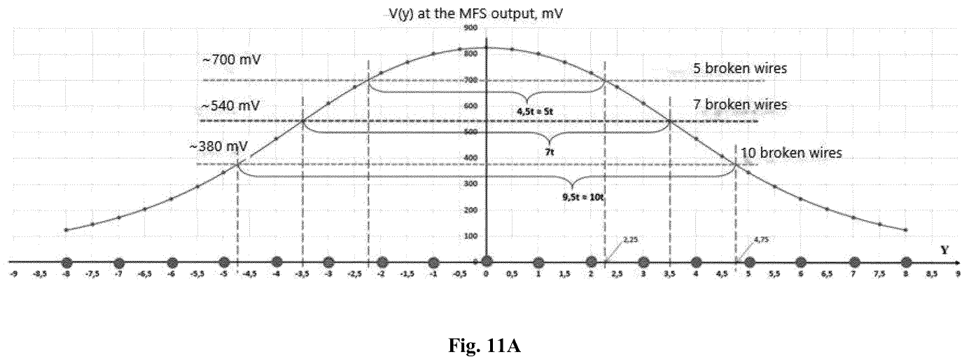

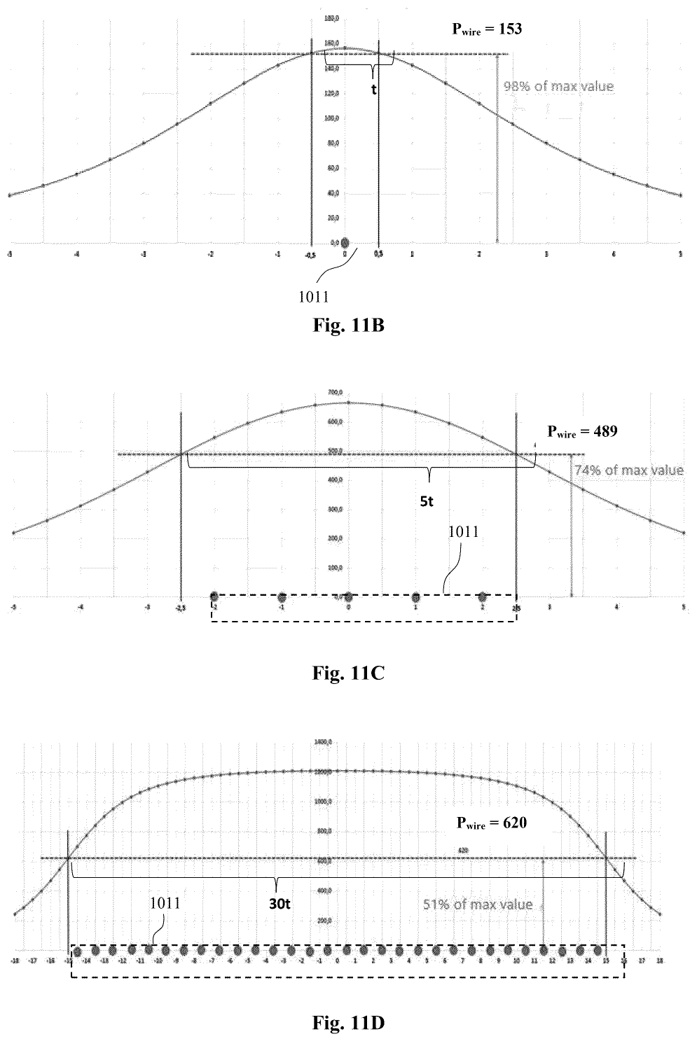

FIG. 11A shows an example of a model calculation for signal levels from MFSs that register the longitudinal component of the magnetic field Bₓ from 7 (seven) broken wires (red indicates the broken wires, blue indicates intact wires) at a distance h₄=4t, along with various threshold levels and the corresponding calculated number of broken wires. It is evident that the signal width at the threshold level P_{wire}=540 m V (the area of the signal above 540 mV) in wire step units t is 7, which exactly corresponds to 7 broken wires in the damage. Therefore, the threshold value P_{wire}=540 mV can be considered as the correctly chosen threshold value.

However, if the threshold value P_{wire}=540 mV is increased or decreased by 30%, the corresponding calculated number of broken wires in the damage, rounded, will be 5 or 10, respectively, which is off by 2-3 wires from the true number of broken wires—7 (the average error in this example is 36%). Additionally, the calculated number of broken wires, 5 and 10, for threshold values P_{wire} 700 mV and 380 mV, respectively, differs by a factor of 2 (the absolute signal values in mV are conditional, as all calculations are done with the proportionality constant C in the formula for V(y)). This model calculation clearly shows that the threshold signal levels P_{wire} need to be calibrated.

Mathematical modeling methods have established that the level and shape of the signal from the MFS (121), as well as the appropriate threshold value for the correct determination of the number of broken wires, depend both on the distance at which the MFS (121) is located above the plane of the wires h₄, and on the number of broken wires.

The calculation of the signal distribution V(y) and the optimal threshold level for accurate determination of the damage size for various numbers of broken wires and the MFS location at a distance h₄=4t from the plane of the wires is shown in the graphs in FIGS. 11B to 11G (with red indicating the broken wires). The optimal threshold level is the one at which the signal width across the conveyor at the threshold level, divided by the step of the wires t, gives the number of actually damaged wires (1011), or, in other words, the signal width in wire step units equals the number of broken wires. From the calculations, it is evident that the absolute value of the threshold level P_{wire} for determining the damage size lies within a wide range of values, depending on the number of broken wires: 153 mV for 1 broken wire, 489 mV for 5 broken wires, and 620 mV for 30 broken wires (the absolute signal values are conditional, as all calculations are made with the proportionality constant C in the formula for V(y)).

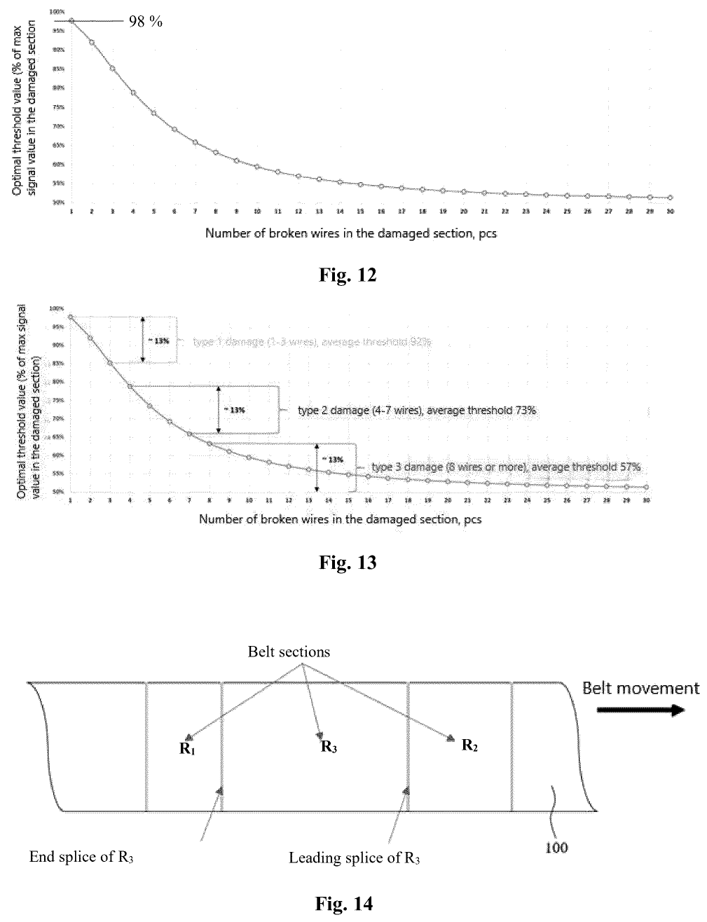

As a result of the modeling, it was found that the optimal threshold level as a percentage of the maximum signal value in the damage area has a certain dependency on the number of broken wires. In particular, with a large number of broken wires in the damage, the optimal threshold level tends to 50% of the maximum signal value, and with a small number of broken wires, it tends toward values close to 100%. FIG. 12 shows the diagram for calculating the optimal threshold level as a percentage of the maximum signal value in the damage area for the example with the MFS (121) located at a distance of h₄=4t from the wire plane, depending on the number of broken wires in the damage. Thus, the approach of using a relative threshold level as a percentage of the maximum signal value in the damage area can be used to find the optimal threshold level.

As an example, let's consider several options for determining the optimal threshold value P_{wire}.

### Option No. 1

As an option for determining the optimal threshold level, one can take the average value of the maximum and minimum percentages across all damage sets, from 1 (one) broken wire and more. For the example with a distance of h₄=4t, this would be 74%=(50%+98%)/2.

### Option No. 2

By being able to model the signal from damage with any number of broken wires, numerical iterative methods can be used to solve the problem of finding the optimal threshold level in percentage (%) at which the error in determining the number of broken wires is minimized across all damage sets, from 1 to N broken wires. In this example, as the first iteration, the threshold level of 74% taken in Option No. 1 can be used.

### Option No. 3

Use differentiated threshold levels for several classes of damage, for example, all damage can be divided into three classes: minor damage—a few broken wires, major damage—a large number of broken wires, and intermediate damage—a moderate number of broken wires.

In this case, the computational unit (140) sets the threshold level for background noise filtering P_{background}, below which no signals are considered. This is done to filter out signals recorded by the scanner (120) from partial (sub) wire damage (where only some strands/wires in the wire are damaged) and various noise artifacts.

### Evaluation of the Threshold Value for Background Noise Filtering P_{background}

In this solution, the threshold value for background noise filtering P_{background} can be evaluated based on the fact that signals below the threshold level for minimal damage (one broken wire) do not need to be considered. In this example, for Option No. 1, the optimal threshold value is 74% of the maximum signal from one broken wire V_{max N=1}, i.e.

$${P}_{b a c k g r o u n d} = 0.74 * {V}_{max N = 1}$$

Additionally, the ratio of the maximum signals for one broken wire V_{max N=1} and a large number of broken wires V_{max N>>1} asymptotically approaches saturation as the number of broken wires N increases) can be calculated. This is essentially the maximum signal in the splice connection V_{max splice}, where the number of technically broken wires reaches its maximum in the conveyor. In the given example, V_{max splice}=V_{max N>>1} can be taken as the maximum signal from 30 broken wires V_{max N=30}, then:

$$\begin{matrix}{V}_{max splice} = {V}_{max N >> 1} = {V}_{max N = 30} = 1208 mV \\ {V}_{max splice} / {V}_{max N = 1} = 1208 mV / 156 mV = 7.74 \\ {V}_{max N = 1} = {V}_{max splice} / 7.74\end{matrix}$$

Substituting into the expression for the threshold value for background cutoff P_{background}, we get

$${P}_{b a c k g r o u n d} = 0.74 * {V}_{max N = 1} = 0.74 * {V}_{max splice} / 7.74 = 0.1 * {V}_{max splice}$$

This calculation shows that the threshold value for background cutoff P_{background} is an order of magnitude lower than the maximum signal level in the joint connection. Therefore, as an initial approximation, the threshold value for P_{background} can be taken as the maximum signal value in the joint connection, reduced by one order of magnitude.

The threshold signal values used for analyzing the magnetic image of the belt (100), obtained with the scanner (120), allow for more precise and effective registration of emerging damage, as well as the accurate determination of joint connections. This is because, when determining the damage size of the wires and the condition of the joint connections using the computing block (140), the obtained magnetic images are compared with one or more threshold signal values P_{wire} set for wire analysis, as well as with one or more threshold signal values P_{splice} set for joint connection analysis, with P_{splice}≥P_{wire}≥P_{background}.

Next, let's consider an example of classifying wire damage into groups (classes) depending on the number of broken wires. The classification can be done, for example, by dividing into three groups, with the maximum equal ‘spread’ in percentages within the group, as shown in FIG. 13. In this case, the ‘spread’ in each group is approximately ˜13%.
1st group (minor damage): 1-3 broken wires;
2nd group (medium damage): 4-7 broken wires;
3rd group (major damage): 8 or more broken wires.

For each group, the threshold value P_{wire} is determined as a percentage of the maximum signal. The percentage value for each group can be determined, for example, as the arithmetic mean of the maximum and minimum values in the group:
92%—for minor damage (1-3 broken wires);
73%—for medium damage (4-7 broken wires);
57%—for major damage (8 or more broken wires).
   Other methods of determining the threshold value P_{wire} as a percentage for each group are also possible, such as the arithmetic mean of all values in the group, or it can be determined using numerical iteration methods to find the optimal threshold percentage for each group, where the error in determining the number of broken wires in the damage is minimized across the entire set of damages in this group. As the first iteration, the threshold percentage can be taken as the arithmetic mean of the maximum and minimum values in the group or all values in the group.

The algorithm for applying differentiated thresholds P_{wire} can represent a method of successive iterations. Let's consider the algorithm example described above:

First, for all damages, the lowest threshold percentage of 57% is used. If the calculated number of broken wires in the damage with this threshold is eight or more, this number is accepted. If the number of wires is less than eight, the threshold is increased to the next level of 73%. If, after that, the calculated number of broken wires falls within the range of 4-7 wires, this number is accepted. If the calculated number of broken wires is less, the next threshold level of 92% is applied, and the number of broken wires at this threshold is accepted.
The algorithm can also be applied in the reverse direction, starting with the highest percentage threshold of 92%, and then decreasing step by step to 73% and 57%, respectively. A combination of the above-described algorithms can be used, for example, each damage is analyzed by both algorithms—one increasing the percentage threshold (57%->73%->92%) and the other decreasing the percentage threshold (92%->73%->57%), and the number of damaged (broken) wires in the damage is taken as the arithmetic mean of the number of damaged wires obtained from the execution of each of the two algorithms.

The threshold value P_{wire} can be set automatically for each wire damage at a level corresponding to a certain percentage of the maximum signal from this wire damage. This percentage can be determined automatically, for example, based on the distance of the scanner (120) from the plane of the wires h₄ in units of the wire step t, based on the distance h₃ from the scanner (120) to the surface of the conveyor belt (100), and the parameters of the conveyor belt (100) design—t, d_{wire}, h₁, h₂ (Table 2). Moreover, the threshold value setting can be carried out automatically and differentiated for several damage classes with different numbers of broken wires.

The splice connections, due to the larger number of exposed (technologically broken) wires, have the highest signal strength and pixel area compared to the damaged area of the wires. Therefore, to detect only splice connections, higher threshold values are used for the signal strength and pixel count, so that the wire damage is filtered out (discarded). After all splice connections are identified, the aforementioned calibration system is used to correctly determine the number of broken wires at the damage locations.

When performing magnetic mapping of the conveyor belt, the system first registers all splice connections and their mutual positioning. During subsequent passes of the belt on the conveyor, it identifies repeating splices (repetition of the pattern of splice positions), which allows the system to identify all splice connections without repetition and obtain the total length of the conveyor belt. The splice connections on the magnetic image of the conveyor belt are used as reference points (coordinate system) to determine the positions of belt damages in the longitudinal direction along the belt (X-axis coordinate). Each damage has a longitudinal coordinate from the first splice and/or from the leading and/or closing splice connection of the belt section where the damage is located or from any other splice connection or from a location on the belt situated at a specified distance from the selected splice connection. The first splice connection is considered to be the leading or closing splice connection of the belt section with a designated ranking number based on length, where the first section has the shortest length, and subsequent sections have increasing lengths relative to the previous one. The splice connection of the belt section with the designated ranking number, located first in the direction of the belt, is the leading splice, while the second one is the closing splice, or the first splice connection is set manually. For the operation of the conveyor, the belt is spliced into an endless ring made of individual belt pieces (sections), so each belt section has two splice connections at its ends. The splice connection located first in the direction of the belt is called the leading splice, and the second splice connection along the belt direction is the closing splice.

Additionally, the conveyor belt may be fitted with a marker, such as a visual, magnetic, radio-frequency (RFID, NFC, etc.), or another type, which is used to confirm the registration of the full rotation of the conveyor belt during scanning, obtaining the full length of the belt, and the reference point for the longitudinal coordinate along the belt. This allows obtaining data on the full length of the belt, with images of all splice connections and wire damages on the belt, indicating the longitudinal coordinates along the belt. In this case, belt sections (100) can be assigned sequential numbers from the shortest to the longest, taking into account their increasing length. Sequential numbers can be applied to rank the belt sections R1-R3 (100) by length, as shown in FIG. 14.

In the analysis of the received magnetic images, the computational unit (140) performs the determination of the wire damage area and the area of the pole lines of the splice step based on the threshold values of P_{wire} and P_{splice}, established for the MFS (121). A threshold area level, S_{wire}, is applied for determining wire damage and a threshold area level, S_{splice}, is applied for determining the pole lines of the splice step and the splice connection itself. Here, S_{splice} is greater than S_{wire}. S_{splice} and S_{wire} can be determined by the number of pixels on the magnetic image. To select S_{splice} and S_{wire}, a preliminary analysis of the magnetic image can be performed. For example, taking the threshold value of P_{splice} at 50% of the maximum signal in the splice connection, followed by the calculation of the area of the pole lines of the splice step for this threshold value of P_{splice}, where the threshold value of S_{splice} is taken as half of this area. If necessary, the value of P_{splice} and S_{splice} can be increased or decreased to ensure that all existing splice connections on the belt are registered and nothing more. To select S_{wire}, a calibration sample of the conveyor belt with one broken wire can be used. For this calibration sample, a threshold value of P_{wire} is selected at which the system determines that the number of broken wires is exactly one. Then, the system determines the damage area of one wire for the selected threshold value of P_{wire}. The value of S_{wire} is taken as half of this area. If necessary, the values of P_{wire} and S_{wire} can be increased or decreased to avoid registering partial wire damage and noise artifacts or loss of registration of a single wire break.

Using the above data, when processing the signals received from the scanner (120), the fact of registering the pole lines of the splice step and the splice connection itself in the magnetic image is determined if the signal exceeds or equals the threshold value P_{splice}, and if the area of the magnetic anomaly, determined based on P_{splice}, exceeds or equals the value S_{splice}. The registration of wire damage on the magnetic image is determined by the computational unit (140) if all of the following conditions are met: the signal exceeds or equals the threshold value P_{wire}, the area of the magnetic anomaly, determined based on P_{wire}, exceeds or equals the value S_{wire}, and if the magnetic anomaly is not registered as a pole line of the splice step. Magnetic anomalies for which the received signal level P_{wire} is lower than P_{background} are not considered, as they characterize background artifacts.

In one of the specific implementation examples, the computational unit (140) is connected to the conveyor belt control system, which allows for the automatic stopping of the conveyor in case of critical damage. The connection of the computational unit (140) to such a system can be implemented through relay outputs, the Modbus protocol, or networks like Profibus, Profinet, or other types of networks.

The conveyor stop is initiated by the computational unit (140), which generates a signal that is transmitted to the conveyor control system. This signal can be generated when a specified critical damage level is exceeded, which is characterized by one or more parameters, such as:
The size of the damage, measured by the number of broken wires or their percentage share of the total number of wires in the belt;
The total number of broken wires from all recorded damages over a section of the belt of a given length or their percentage share of the total number of wires in the belt.

Additionally, the conveyor can be stopped when a given change in the state parameter of the splice connection relative to the specified threshold value for at least one of the parameters selected from the group: length of the splice connection, angle of inclination of the pole lines of the splice step, degree of linearity of the pole lines of the splice step, distance between different pole lines of the splice step, area of the pole lines of the splice step, area of the splice connection.

The claimed system (10) and its operating principle not only detect damage and splice connections in the belt (100), but also allow these to be moved to a designated spot on the conveyor for detailed inspection and repair. For these purposes, the computational unit (140) is equipped with the option to track the position of the scanner (120) relative to the moving belt in real-time (on-line), which can also be displayed on the screen of an external device (150), allowing the position of the scanner (120) on the magnetic image of the belt to be seen with the longitudinal coordinate along the belt indicated.

The display of the magnetic image in the device's GUI (150) can be performed interactively, allowing users to select the damages of interest and track them (for example, by marking them with a flag in the program), so that an alert signal will be triggered a certain number of meters before the selected damage approaches the scanner's (120) location or another place on the conveyor at a specific distance from the scanner. This gives the conveyor operator time to issue a stop command.

As mentioned above, if the system is stationary, it can be connected to the conveyor control system via relay outputs or through the Modbus protocol or networks such as Profibus, Profinet, or other types of networks. This allows for the automatic stopping of the conveyor without operator intervention, so that the belt damage or splice connection will be at a designated distance from the scanner in a specific location for inspection and/or repair.

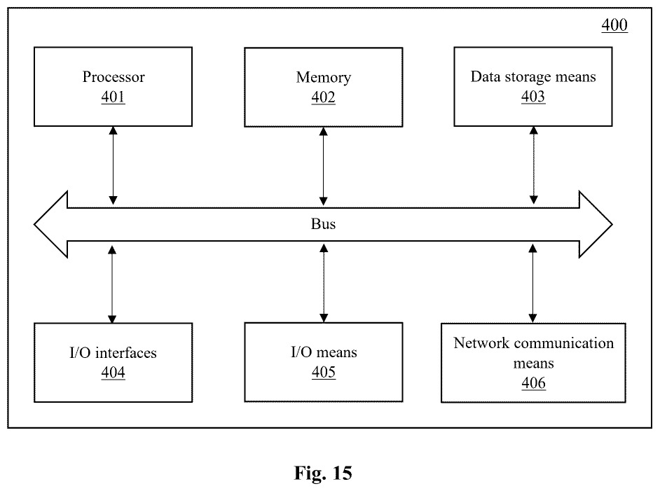

FIG. 15 presents a general example of the computational unit (device) (400), such as a computational unit (computational module), computer, server, laptop, smartphone, SoC (System-on-a-Chip), etc., which can be used for the full or partial implementation of the claimed solution, particularly for the implementation of devices (140, 150). In general, the device (400) contains components such as: one or more processors (401), at least one random-access memory (402), data storage means (403), input/output interfaces (404) including relay outputs for connecting to conveyor motion control controllers, I/O means (405), and network communication means (406).

The processor (401) of the device performs the main computational operations required for the functioning of the device (400) or the functionality of one or more of its components. The processor (401) executes the necessary machine-readable commands stored in the random-access memory (402).

The memory (402) is typically in the form of RAM and contains the necessary software logic to provide the required functionality. The data storage means (403) may be in the form of HDD, SSD drives, RAID arrays, network storage, flash memory, optical data storage (CD, DVD, MD, Blu-ray discs), etc. The means (403) allows for long-term storage of various types of information, such as magnetic images, request processing history (logs), user identifiers, camera data, images, etc.

The interfaces (404) are standard means for connecting and working with computational devices. The interfaces (404) may include relay connections, USB, RS232/422/485, RJ45, LPT, UART, COM, HDMI, PS/2, Lightning, Fire Wire, etc., for operation with protocols like Modbus and networks such as Profibus, Profinet, or other types of networks. The selection of interfaces (404) depends on the specific implementation of the device (400), which can be a computational unit (computational module), for example, based on a CPU (one or more processors), microcontroller, personal computer, mainframe, server cluster, thin client, smartphone, laptop, etc., as well as any external devices connected to it.

As input/output means (405), the following may be used: a keyboard, joystick, display (touchscreen), projector, touchpad, mouse, trackball, light pen, speakers, microphone, etc.

The network interaction means (406) are selected from a device that provides network data reception and transmission, such as an Ethernet card, WLAN/Wi-Fi module, Bluetooth module, BLE module, NFC module, IrDa, RFID module, GSM modem, etc. This means (406) enables data exchange over a wired or wireless communication channel, such as WAN, PAN, LAN, Intranet, Internet, WLAN, WMAN, or GSM, quantum (fiber-optic) data transmission channel, satellite communication, etc. The components of the device (400) are generally connected via a common data bus.

The materials in this application present a preferred disclosure of the implementation of the claimed technical solution, which should not be used as a limitation for other, specific embodiments of its implementation that do not go beyond the requested scope of legal protection and are obvious to specialists in the relevant technical field.

1. A system for scanning the condition of a wire-reinforced conveyor belt, comprising:
at least one magnet located across the conveyor belt and providing magnetization of the steel wires of the conveyor belt;
at least one multi-channel scanner containing a group of magnetic field sensors (MFS) and ensuring scanning of the conveyor belt to obtain magnetograms displaying signals from the magnetic field scattering (SMF) in the areas of splice connections and steel wire damage;
a computational unit that receives signals from the scanner and performs:
a) processing of the obtained magnetograms to determine the size of steel wire damage and/or the condition of splice connections in the conveyor belt, wherein the condition of splice connections is characterized by at least their length;
b) determination of the longitudinal and/or transverse coordinates of steel wire damage and/or the longitudinal coordinates of splice connection locations;
c) transmission of processed data from the magnetograms obtained at steps a) and b) to an external device.

2. (canceled)

3. The system of claim 1, wherein the group of MFS is arranged in a single row or at least two rows.

4. The system of claim 3, wherein the rows of MFS are arranged in a checkerboard pattern.

5. The system of claim 1, wherein the MFS register at least one SMF component, selected from the group: longitudinal Bₓ, transverse B_{y}, or perpendicular B_{z}.

6. The system of claim 1, wherein the scanner contains magnetic flux concentrators that provide passive magnetic amplification and increased output sensitivity of the MFS without increasing its own electrical noise.

7. The system of claim 6, wherein the flux concentrators are integrated into the MFS.

8. The system of claim 6, wherein the magnetic flux concentrators are made in the form of rods or plates.

9. The system of claim 1, wherein the transverse coordinate across the width of the belt is measured from the edge or center of the conveyor belt.

10. The system of claim 1, wherein a screen is installed above the scanner to protect against external magnetic fields.

11. (canceled)

12. (canceled)

13. (canceled)

14. (canceled)

15. The system of claim 1, which additionally includes a belt length counter that generates signals transmitted to the computational unit, characterizing the longitudinal length of the conveyor belt.

16. The system of claim 15, wherein the belt length counter is a non-contact tachometer or proximity sensor mounted on the conveyor drum or roller, or an encoder with a wheel contacting the moving belt.

17. The system of claim 16, wherein the belt length counter is integrated into the scanner or the magnet.

18. (canceled)

19. The system of claim 1, wherein the external device is a monitor, interactive screen, computer, laptop, tablet, smartphone, removable data storage device, PLC for conveyor control, or a remote control system.

20. (canceled)

21. (canceled)

22. (canceled)

23. The system of claim 1, wherein the computational unit additionally determines at least one of the following parameters: splice serial number, angle of inclination of the pole lines of the splice step, linearity degree of the pole lines of the splice step, area of the pole lines of the splice step, distance between different pole lines of the splice step.

24. The system of claim 1, wherein the computational unit is configured to filter out signals registered by the MFS that are below a threshold value for background signal cutoff, P_{background}.

25. The system of claim 1, wherein, when determining the size of wire damage and the condition of splices using the computational unit, the obtained magnetograms are compared with at least one threshold signal value, P_{wire}, established for analyzing wires, and at least one threshold signal value, P_{splice}, for analyzing splices, with the relationship P_{splice}≥P_{wire}≥P_{background}.

26. (canceled)

27. (canceled)

28. (canceled)

29. (canceled)

30. (canceled)

31. (canceled)

32. (canceled)

33. (canceled)

34. (canceled)

35. (canceled)

36. (canceled)

37. (canceled)

38. (canceled)

39. The system of claim 1, wherein the computational unit is connected to the conveyor belt's control system.

40. (canceled)

41. The system of claim 39, wherein the computational unit is capable of generating a signal for the conveyor belt control system to stop the conveyor belt when a given level of wire damage is exceeded, characterized by at least one parameter selected from the group: the size of the damage, measured by the number of broken wires or their percentage of the total number of wires in the belt; the total number of broken wires from all recorded damages on a section of the belt of a given length or their percentage of the total number of wires in the belt.

42. The system of claim 39, wherein the computational unit is capable of generating a signal for the conveyor belt control system to stop the conveyor belt when a given change in the state parameter of the splice connection relative to a given threshold value is detected, with at least one parameter selected from the group: the length of the splice connection, the angle of inclination of the pole lines of the splice step, the degree of linearity of the splice step lines, the distance between different pole lines of the splice step, the area of the splice step pole lines, the area of the splice connection.

43. (canceled)

44. (canceled)

45. (canceled)

46. (canceled)

47. A method of scanning the state of a wire-reinforced conveyor belt, comprising the steps of:
a) magnetizing the wires of the conveyor belt using at least one magnet located across the conveyor belt;
b) scanning the conveyor belt with at least one multi-channel scanner containing a group of magnetic field sensors (MFS), during which magnetic images are obtained, displaying signals from the scattering magnetic field (SMF) in the areas of splice connections and wire damages;
c) receiving the signals generated by the scanner in the computational unit, which ensures:
i) processing the obtained magnetic images to determine the size of the wire damage and/or the condition of the splice connections in the conveyor belt, where the condition of the splice connections is characterized by at least their length;
ii) determining the longitudinal and/or transverse coordinates of the wire damages and/or the longitudinal coordinates of the splice connection locations;
iii) transmitting the processed magnetic image data obtained in steps i) and ii) to an external device.
